(19) United States
(12) Patent Application Publication
(10) Pub. No.: US 2012/0037213 A1
(43) Pub. Date: Feb. 16, 2012

(54) BACKSHEET FOR A PHOTOVOLTAIC MODULE

(75) Inventor: Stephen Yau-Sang CHENG, Hong Kong (HK)

(73) Assignee: Du Pont Apollo Limited, Hong Kong (HK)

(21) Appl. No.: 13/190,497

(22) Filed: Jul. 26, 2011

Related U.S. Application Data
(60) Provisional application No. 61/372,464, filed on Aug. 11, 2010.

(51) Int. Cl. H01L 31/048; B32B 3/26

(52) U.S. Cl. 136/251; 428/304.4; 428/315.5; 428/319.1; 428/317.7

(57) ABSTRACT

Disclosed herein is a backsheet for a photovoltaic module. The backsheet includes a protective layer and a layer of polymeric foam having a predetermined pore volume. The polymeric foam has a bulk density of about 0.01 g/cm³ to about 0.6 g/cm³ and is derived from an olefin monomer. The protective layer and the polymeric foam layer are respectively situated on the opposite surfaces of the backsheet, and the polymeric foam layer is for connecting to a photovoltaic member.

### RELATED APPLICATIONS

This application claims priority to U.S. Provisional Application Ser. No. 61/372,464, filed Aug. 11, 2010, which is herein incorporated by reference.

### BACKGROUND

1. Field The present disclosure relates to an encapsulation. More particularly, the present disclosure relates to a backsheet for a photovoltaic module.

2. Description of Related Art

Solar energy has gained much research attention for being a seemingly inexhaustible energy source. For such purpose, photovoltaic modules that convert solar energy directly into electrical energy are developed.

In general, the photovoltaic module mechanically supports the solar cells, and protects the solar cells against environmental degradation. The photovoltaic module generally comprises a rigid and transparent protective front panel such as glass, and a rear panel or sheet, which is typically called a backsheet. The front panel and backsheet encapsulate the solar cell(s) and provide protection from environmental damage.

A known backsheet comprising a weather-resistant layer, a moisture-barrier layer and an insulating layer is disclosed in the prior art. In this technology, a layer of polyethylene terephthalate (PET) is adopted as the insulating layer. However, when a polyethylene terephthalate layer is employed in the backsheet, a tie layer is further required to insure sufficient adhesion with the encapsulant which bonds the backsheet to the solar cell. In addition, polyethylene terephthalate undergoes an orientation process in order to produce a sheet useful for the fabrication of the photovoltaic module, and renders the backsheet expensive. In view of the above, there exists in this art a need of an improved backsheet, which would have a lower cost and provide an excellent electrical insulation.

### SUMMARY

According to one aspect of the present disclosure, a backsheet for a photovoltaic member is provided. The backsheet includes a protective layer and a layer of polymeric foam. The polymeric foam has a bulk density of about 0.01 g/cm³ to about 0.6 g/cm³ and is derived from an olefin monomer. The protective layer and the polymeric foam layer are respectively situated on two opposite surfaces of the backsheet.

According to another aspect of the present disclosure, a photovoltaic module is provided. The photovoltaic module includes a backsheet described above and a photovoltaic member for converting light into electricity. The photovoltaic member is positioned at the side of the polymeric foam layer of the backsheet.

### BRIEF DESCRIPTION OF THE DRAWINGS

The present disclosure can be more fully understood by reading the following detailed description of the embodiments, with reference made to the accompanying drawings as follows:

FIG. 1 is a cross-sectional view schematically illustrating a backsheet according to one embodiment of the present disclosure;

FIG. 2 is a cross-sectional view schematically illustrating a backsheet according to another embodiment of the present disclosure; and

FIG. 3 is a cross-sectional view schematically illustrating a photovoltaic module according to one embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

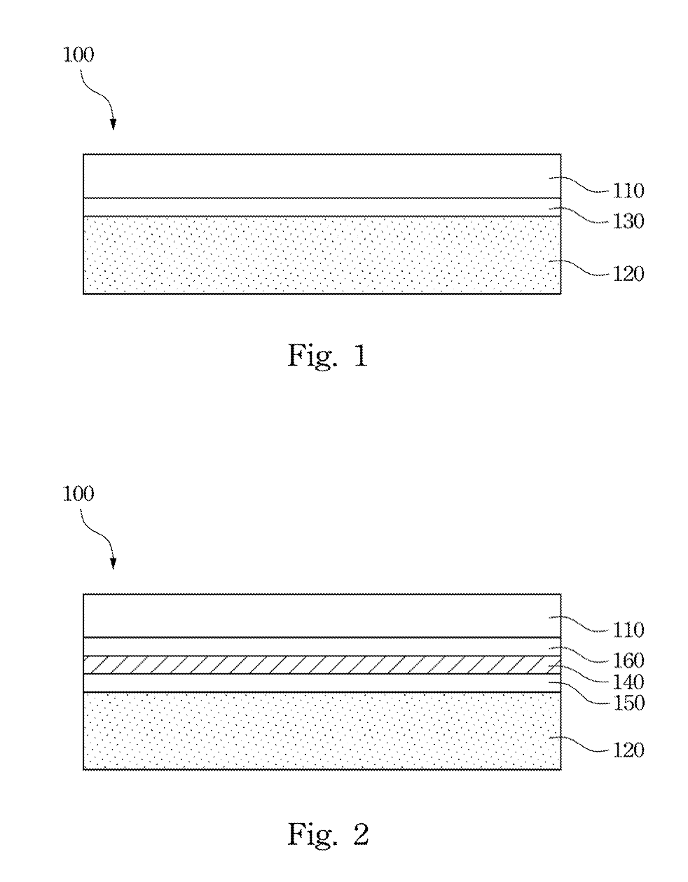

FIG. 1 is a cross-sectional view schematically illustrating a backsheet 100 according to one embodiment of the present disclosure. The backsheet 100 is operable to protect a photovoltaic member (not shown in FIG. 1), which converts sunlight into electricity. As depicted in FIG. 1, the backsheet 100 comprises a layer of polymeric foam 110 and a protective layer 120. The polymeric foam layer 110 and the protective layer 120 are respectively situated on the opposite surfaces of the backsheet 100, and the polymeric foam layer 110 is for connecting to the photovoltaic member.

The polymeric foam 110 has a predetermined pore volume, and the bulk density of the polymeric foam 110 is about 0.01 g/cm³ to about 0.6 g/cm³. The layer of the polymeric foam 110 is for connecting to the photovoltaic member, and requires a property of electrical insulation to prevent an electric current generated by the photovoltaic member from leakage via the backsheet 100. The insulating property of the polymeric foam 110 depends on the pore volume therein. In particular, the insulating property of the polymeric foam 110 may be enhanced when the ratio of the pore volume to the bulk volume (hereinafter referring to “porosity”) increases. Furthermore, the higher the porosity, the lower the bulk density of the polymeric foam 110. However, when the bulk density of the polymeric foam 110 is less than a certain value, for example 0.01 g/cm³, the mechanical strength of the polymeric foam 110 becomes too weak and is difficult to be applied in the backsheet 100. In contrast, when the bulk density of the polymeric foam 110 is greater than a certain value, for example 0.6 g/cm³, the porosity of the polymeric foam 110 is too low, meaning more materials are used and the cost savings become negated. In one specific example, the bulk density of the polymeric foam ranges from about 0.2 g/cm³ to about 0.46 g/cm³.

In one embodiment, the polymeric foam 110 may comprise a plurality of “closed cell”. The term “closed cell” refers to a structure existed in the polymeric foam, in which a void space is enclosed and surrounded by the structure of the closed cell. In this case, the polymeric foam 110 may provide a desired electrical insulation and mechanical strength. However, the present disclosure is not limited thereto, and a polymeric foam having a structure of open cells may be employed in the present disclosure as well.

In another embodiment, the polymeric foam 110 comprises a cross-linked structure for increasing the mechanical strength of the polymeric foam. In particular, the cross-linked structure in the polymeric foam 110 may be formed by illuminating an electron beam (E-beam) to the polymeric foam 110.

The polymeric foam 110, also requires a property of non-hydrolysis since the backsheet 100 is usually installed outdoors. The polymeric foam 110 derived from an olefin monomer may provide both desired properties of insulation and non-hydrolysis. Suitable materials for the polymeric foam 110 include, but are not limited to, polyethylene, copolymer of ethylene and propylene, copolymer of ethylene and 1-butene, copolymer of ethylene and 1-hexene, copolymer of ethylene and 1-octene, copolymer of ethylene and vinylacetate, copolymer of ethylene and methylacrylate, copolymer of ethylene and ethylacrylate, copolymer of ethylene and acrylic acid, and copolymer of ethylene and maleic anhydride.

The pore in the polymeric foam 110 may be formed by any method known in the art. In one embodiment, the pore in the polymeric foam 110 may be generated by a physical blowing agent, which does not chemically react with the polymeric material. Suitable physical blowing agents include, but are not limited to, water, nitrogen gas, carbon dioxide, and gaseous hydrocarbons such as pentane. In another embodiment, the pore in the polymeric foam 110 may be formed by a chemical blowing agent, which chemically react within the polymeric matrix and thus generating gas that causes the foaming process. Suitable chemical blowing agents may be sodium bicarbonate or azobisformamide, for example.

In some embodiments, the polymeric foam layer 110 may comprise a filler or additive. In one example, the filler or additive added in the polymeric foam layer 110 may be a desiccating agent for absorbing moisture that leaks into the photovoltaic module. The desiccating agent, for example, may be a zeolite having a pore size of at least 3 Angstroms.

The insulating property of the polymeric foam 110 also depends on the thickness of the polymeric foam layer 110. In one embodiment, the thickness of the polymeric foam layer 110 is greater than 0.05 mm, specifically greater than 0.1 mm, more specifically greater than 0.2 mm. In some examples, the thickness of the polymeric foam layer 110 is about 0.2 mm to about 6.4 mm.

Typically, a conventional backsheet is adhered to a photovoltaic member by an additional ethylene-vinyl acetate copolymer (EVA) film. For the purpose of firm bonding, a tie layer for connecting to the EVA film is needed in the prior art because the insulating layer such as PET can not provide sufficient adhesion with the EVA film. In one embodiment of the present disclosure, the backsheet 100 has a layer of polymeric foam 110 disposed on an outmost surface thereof and may provide excellent adhesion with the EVA film. Therefore, the tie layer used in the prior art is no longer required. Moreover, the layer of polymeric foam 110 may simultaneously provide a function of insulation, and therefore a polyethylene terephthalate (PET) layer may also be eliminated. Furthermore, the layer of polymeric foam 110 disclosed herein eventually needs a less amount of material compared to a solid layer. Therefore, the backsheet disclosed herein is cost-effective.

The protective layer 120 is disposed on an outmost surface that is opposite to the layer of polymeric foam 110, and provides a function of weather resistance. Usually, the protective layer 120 is directly exposed to the ambient environment. The protective layer may be made of a material such as metal, polymer, inorganic composition or a combination thereof. In some embodiments, protective layer 120 may be made from PE, PC, fluorinated polymer or Nylon.

An additional moisture-barrier layer is not required when the backsheet 100 disclosed herein is applied in a photovoltaic module which is not so sensitive to moisture, for example, polycrystalline silicon photovoltaic modules. In these applications, the backsheet 100 may lack for a moisture-barrier layer. In one example, the backsheet 100 may further comprise a first adhesive layer 130 disposed between the protective layer 120 and the polymeric foam layer 110, as depicted in FIG. 1. The first adhesive layer may be made from a copolymer of ethylene and acrylic acid, or a copolymer of ethylene and maleic anhydride. In some examples, the thickness of the first adhesive layer 130 is about 0.01 mm to about 0.5 mm.

Optionally, the backsheet 100 may further comprise a moisture-barrier layer 140 disposed between the polymeric foam layer 110 and the protective layer 120, as depicted in FIG. 2. When the backsheet 100 disclosed herein is applied in a photovoltaic module which is sensitive to moisture, such as an amorphous silicon photovoltaic module, the moisture-barrier layer 140 may provide a sufficient resistance to moisture. In these examples, the moisture-barrier layer 140 may comprise a layer of aluminum.

In one embodiment, backsheet 100 may further comprise a second adhesive layer 150 disposed between the moisture-barrier layer 140 and the protective layer 120. The second adhesive layer 150 may comprise a copolymer of ethylene and acrylic acid or a copolymer of ethylene and maleic anhydride, for example. In addition, the second adhesive layer 150 may be about 0.01 mm to about 0.5 mm in thickness.

In another embodiment, backsheet 100 may further comprise a third adhesive layer 160 disposed between the moisture-barrier layer 140 and the polymeric foam layer 110. The third adhesive layer 160 may be the same as or different from the second adhesive layer 150.

In some embodiment, the moisture-barrier layer 140 may be in direct contact with the polymeric foam layer 110, without the third adhesive layer 160 disposed therebetween. Similarly, the moisture-barrier layer 140 may directly contact the protective layer 120, without the second adhesive layer 150 disposed therebetween.

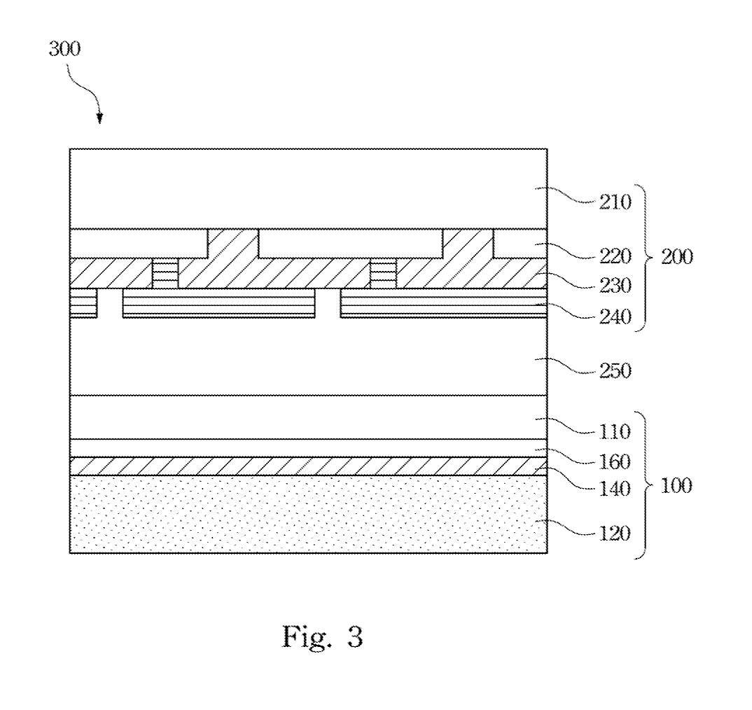

According to another aspect of the present disclosure, a photovoltaic module is provides. FIG. 3 is a cross-sectional view schematically illustrating a photovoltaic module 300 according to one embodiment of the present disclosure. Referring to FIG. 3, the photovoltaic module 300 comprises a backsheet 100 and a photovoltaic member 200. The backsheet 100 may be any embodiment described hereinbefore. For instance, the backsheet 100 may comprise a layer of polymeric foam 110, a protective layer 120, a moisture-barrier layer 140, and a third adhesive layer 160. The photovoltaic member 200 capable of converting light into electricity is disposed at the side of the polymeric foam layer 110 of the backsheet 100. The protective layer 120 is positioned at the outmost surface of the photovoltaic module 300.

In one embodiment, the photovoltaic member 200 comprises a front transparent substrate 210, a transparent conductive oxide layer 220, a photoelectric conversion layer 230 and a back electrode 240, as depicted in FIG. 3.

The front transparent substrate 210 is disposed on the outmost side of the photovoltaic member 200 in order to protect the photovoltaic module 300 from environmental degradation. In general, the front transparent substrate 210 may be made of glass, and light may be transmitted into the photovoltaic member 200 through the transparent substrate 210.

The transparent conductive oxide layer 220 is disposed on the front transparent substrate 210. In some examples, the transparent conductive oxide layer 220 may comprise zinc oxide (ZnO), fluorine doped tin dioxide (SnO₂:F), or indium tin oxide (ITO). In other examples, the transparent conductive oxide layer 220 has a textured structure (not shown) on the interface between the transparent conductive oxide layer 220 and the photoelectric conversion layer 230 for trapping light that is transmitted into the photovoltaic member 200.

The photoelectric conversion layer 230 for converting light into electricity is disposed between the transparent conductive oxide layer 220 and the back electrode 240. It should be noted that in the present disclosure the term “photoelectric conversion layer” comprises all layers that is needed to absorb the light and convert it into electricity. Various thin film semiconductor materials may be employed in the photoelectric conversion layer 230. Suitable materials include, but are not limited to, amorphous silicon (a-Si:H), polycrystalline silicon, signal crystalline silicon, amorphous silicon carbide (a-SiC), and amorphous silicon-germanium (a-SiGe). In the amorphous silicon embodiment, the photoelectric conversion layer 220 may comprise a p-doped amorphous silicon layer, an intrinsic amorphous silicon layer, and an n-doped amorphous silicon layer (also known as “p-i-n structure”). Further, a plurality of repetitive p-i-n layers (“pin-pin-pin” or “pin-pin-pin-pin”) may sequentially be formed as well. In other examples, the photoelectric conversion layer 230 may comprise GaAs, GIGS, or CdTe.

The back electrode 240 is disposed on the photoelectric conversion layer 230, and in contact with the photoelectric conversion layer 230. In some examples, the back electrode 240 may be made of silver, aluminum, copper, chromium, nickel or transparent conductive oxide, depending on the needs. The electricity generated by the photoelectric conversion layer 230 may be transmitted to an external loading device through the back electrode 240 and the transparent conductive oxide layer 220.

In examples, the photovoltaic module 300 may further comprise a sealing layer 250 which is sandwiched between the polymeric foam layer 110 and the back electrode 240. The sealing layer directly contacts the back electrode 240 and the polymeric foam layer 110 of the backsheet 100, and therefore bonds the photovoltaic member 200 and the backsheet 100 together. In some examples, the sealing layer 250 is a layer of ethylene-vinyl acetate copolymer.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A backsheet for a photovoltaic member, the backsheet comprising a protective layer and a layer of polymeric foam respectively situated on two opposite surfaces of the backsheet, wherein the polymeric foam is derived from an olefin monomer and has a bulk density of about 0.01 g/cm³ to about 0.6 g/cm³.

2. The backsheet according to claim 1, wherein the layer of polymeric foam comprises at least one material selected from the group consisting of polyethylene, copolymer of ethylene and propylene, copolymer of ethylene and 1-butene, copolymer of ethylene and 1-hexene, copolymer of ethylene and 1-octene, copolymer of ethylene and vinylacetate, copolymer of ethylene and methylacrylate, copolymer of ethylene and ethylacrylate, copolymer of ethylene and acrylic acid, and copolymer of ethylene and maleic anhydride.

3. The backsheet according to claim 1, wherein the layer of the polymeric foam has a thickness of greater than about 0.05 mm.

4. The backsheet according to claim 3, wherein the layer of the polymeric foam has a thickness of about 0.2 mm to about 6.4 mm.

5. The backsheet according to claim 1, wherein the bulk density of the polymeric foam ranges from about 0.2 g/cm³ to about 0.46 g/cm³.

6. The backsheet according to claim 1, wherein the layer of polymeric foam comprises a filler.

7. The backsheet according to claim 6, wherein the filler comprises a zeolite having a pore size of at least about 3 Angstroms.

8. The backsheet according to claim 1, wherein the protective layer comprises a material selected from the group consisting of metal, polymer, inorganic composition and a combination thereof.

9. The backsheet according to claim 1, further comprising a first adhesive layer disposed between the protective layer and the layer of the polymeric foam, and wherein the first adhesive layer comprises at least one of a copolymer of ethylene and acrylic acid and a copolymer of ethylene and maleic anhydride.

10. The backsheet according to claim 9, wherein the first adhesive layer has a thickness of about 0.01 mm to about 0.5 mm.

11. The backsheet according to claim 1, further comprising a moisture-barrier layer disposed between the layer of polymeric foam and the protective layer, and wherein the moisture-barrier layer is made of a metallic material.

12. The backsheet according to claim 11, wherein the moisture-barrier layer is in contact with the layer of polymeric foam.

13. The backsheet according to claim 12, further comprising a second adhesive layer disposed between the moisture-barrier layer and the protective layer, and wherein the second adhesive layer comprises a copolymer of ethylene and acrylic acid or a copolymer of ethylene and maleic anhydride.

14. The backsheet according to claim 13, wherein the second adhesive layer has a thickness of about 0.01 mm to about 0.5 mm.

15. The backsheet according to claim 1, wherein the polymeric foam has a cross-linked structure.

16. The backsheet according to claim 1, wherein the layer of the polymeric foam comprises a plurality of closed cells.

17. A photovoltaic module, comprising:
a backsheet set forth in claim 1; and
a photovoltaic member for converting light into electricity and disposed at the side of the polymeric foam layer of the backsheet.

18. The photovoltaic module according to claim 17, wherein the photovoltaic member comprises:
a front transparent substrate;
a transparent conductive oxide layer disposed on the front transparent substrate;
a photoelectric conversion layer disposed on the transparent conductive oxide layer; and
a back electrode disposed on the photoelectric conversion layer.

19. The photovoltaic module according to claim 18, further comprises a sealing layer sandwiched between the polymeric foam layer and the back electrode, and wherein the sealing layer is in direct contact with the back electrode and the polymeric foam layer of the backsheet.

20. The photovoltaic module according to claim 19, wherein the sealing layer is a layer of ethylene-vinyl acetate copolymer.
